(19) United States
(12) Patent Application Publication
(10) Pub. No.: US 2007/0102797 A1
(43) Pub. Date: May 10, 2007

(54) Electrode package for semiconductor device

(75) Inventor: Hiroshi Kimura, Tokyo (JP)

Correspondence Address: REISING, ETHINGTON, BARNES, KISSELLE, P.C., P O BOX 4390, TROY, MI, 48099-4390, US

(73) Assignee: Torex Semiconductor, Ltd.

(21) Appl. No.: 11/645,850

(22) Filed: Dec. 27, 2006

Related U.S. Application Data
(62) Division of application No. 10/979,258, filed on Nov. 2, 2004.

(30) Foreign Application Priority Data
Feb. 23, 2004 (JP) 2004-045978

(51) Int. Cl. H01L 23/02

(52) U.S. Cl. 257/678

(57) ABSTRACT

A plurality of isolated metal layers having the same shapes as electrodes are arranged in a matrix, and molded in a resin plate. The metal layers are exposed from both upper and lower surfaces of the resin plate. A cross-sectional area of each metal layer is increased with depth from the upper surface to the lower surface of the resin plate. A reinforcing frame is provided on a lower surface of the resin plate. The reinforcing frame is formed by a plurality of supports in their longitudinal direction being arranged along the periphery of the resin plate.

### REFERENCE TO RELATED APPLICATION

This application is a divisional of U.S. application Ser. No. 10/979,258 filed Nov. 2, 2004.

### BACKGROUND OF THE INVENTION

This invention relates to an electrode package for a semiconductor device and a molded semiconductor device using the electrode package, in particular, the electrode package used for a resin molding of a leadless surface-mounting type package, and the molded semiconductor device.

A surface mount technology is a technology for directly soldering electrodes mounted on a surface of a semiconductor device onto a printed circuit board. By using the technology, through-holes for a pin insertion system become unnecessary. Further, miniaturization of electric components, substrates, and increase of packaging density are attained. As an electrode package used for the surface-mounting type semiconductor device, for example, an electrodeposited frame as shown in FIG. 5 is disclosed in Japanese Patent Application Laid-Open No. 2002-16181. The electrodeposited frame as configured with a plurality of electrodes isolated from each other, as metal lawyers 8a, 8b in FIG. 5, electrodeposited on a flexible flat metal substrate 9.

A semiconductor device molded in a leadless surface-mounting type package is formed with the electrodeposited frame by the steps described below. First, as shown in FIG. 6A, semiconductor chips 2 are die-bonded on the metal layers 8b. Then, wires 4 connect bonding pads 12 of the semiconductor chips 2 with the metal layers 8a respectively. Each of the metal layers 8b is previously deposited larger than a bottom surface of each semiconductor chip 2. Then, the semiconductor chips 2 wired by the wires 4 are encapsulated by epoxy resin 7. Then, as shown in FIG. 6B, the metal substrate 9 is removed from a resin-molded body 11. Thus, the metal layers 8a, 8b are exposed from a bottom surface of the resin-molded body 11. Then, the semiconductor chips 2 are divided into individual semiconductor devices by cutting the resin molded body 11 along a cutting plane line S.

Since the isolated metal layers 8a, 8b are supported by the metal substrate 9, the electrodeposited frame should be delivered to makers of the semiconductor devices with the metal substrate 9 as shown in FIG. 5. Therefore, the heavy electrodeposited frame should be delivered and a delivery cost is high. Further, with each maker, when producing semiconductor devices, the metal substrate 9 should be removed in a production process of the semiconductor devices. However, since the molded electrodeposited frame is so thin (less than 0.7 mm), cracks are often generated in the resin-molded body 11 when the metal substrate 9 is removed. Further, it is difficult to miniaturize the semiconductor devices unless design of the metal layer 8b is modified corresponding to each shape of various semiconductor chips 2. Therefore, since it is necessary to optimize the electrodeposited frame for each shape of the various semiconductor chips 2, production costs of the semiconductor devices are increased.

For resolving the problems described above, an object of this invention is to provide an electrode package for a semiconductor device, which allows the production cost of the surface-mounting type semiconductor device to be lower, and also provide the semiconductor device using the electrode package.

### SUMMARY OF THE INVENTION

In order to attain the object, according to a first aspect of this invention, there is provided an electrode package including a resin plate; and a plurality of isolated electrodes molded in the resin plate, wherein each of the electrodes is exposed from both upper and lower surfaces of the resin plate.

According to the above, a surface-mounting type semiconductor device can be produced as follows. Firstly, semiconductor chips are mounted on one of the surfaces of the resin plate. Secondly, conductive wires electrically connect the semiconductor chips with corresponding electrodes molded in the resin plate. Thirdly, the semiconductor chip is encapsulated in a resin package. Therefore, owing to the resin plate supporting a plurality of the isolated electrodes, the electrode package is made without a metal substrate, and be lightweight. Further, when producing the semiconductor device using this electrode package, there is no need to remove the metal substrate.

According to this invention, preferably, there is provided the electrode package wherein a cross-sectional area of each of the electrodes is increased with depth from one surface to the other surface of the resin plate.

According to the above, setting the one surface downward and the other surface upward makes it difficult for the electrodes to fall out from the resin plate.

According to this invention, preferably, there is provided the electrode package wherein the electrodes each having a same shape are arranged in a matrix, and molded in the resin plate.

According to the above, the semiconductor chips having various sizes and shapes can be mounted on the resin plate. Therefore, the number of electrode packages applied to the semiconductor chips having various sizes and shapes can be reduced.

According to this invention, preferably, there is provided the electrode package wherein a reinforcing frame is provided on a periphery of the resin plate.

If rigidity of the thin electrode package is small at each production process, it is difficult for production machines to transfer the package. However, according to this invention described above, by providing the reinforcing frame, the rigidity of the electrode package is increased. Therefore, while the production machines transfer the electrode package, the electrode package can be prevented from being damaged.

According to this invention, preferably, there is provided the electrode package wherein the reinforcing frame is formed by a plurality of supports in a longitudinal direction thereof being arranged along the periphery of the resin plate, each end of neighboring supports of the supports being overlapped in a direction perpendicular to the longitudinal direction.

According to a structure described above, when a force caused by a difference between coefficients of thermal expansion of the reinforcing frame and the electrode package adjacent to the reinforcing frame is applied to deform the electrode package, the force is cancelled at the overlapped part. Therefore, the deformation of the electrode package can be prevented.

According to a second aspect of this invention, there is provided a semiconductor device including the electrode package described above, a semiconductor chip mounted on the electrode package and electrically connected to the corresponding electrodes of the electrode package by conductive wires, and a resin package for encapsulating the wired semiconductor chip.

According to the above, owing to the electrode package used for producing the semiconductor device, there is no need to remove the metal substrate during the production. Therefore, a production cost of the semiconductor device can be reduced.

According to a third aspect of this invention, there is provided the semiconductor device including the electrode package described above, the semiconductor chip mounted on the other surface of the resin plate of the electrode package and electrically connected to the corresponding electrodes of the electrode package by conductive wires, and a resin package for encapsulating the wired semiconductor chip.

According to the above, owing to the electrode package used for producing the semiconductor device, there is no need to remove the metal substrate during the production. Further, mounting the semiconductor chip on the other surface of the resin plate of the electrode package makes it difficult for the electrode, on which the semiconductor chip is mounted, to fall out from the resin plate, even if a bond between the semiconductor chip and the electrode is broken. Therefore, the production cost of the semiconductor device can be further reduced.

### BRIEF DESCRIPTION OF THE DRAWINGS

FIG. 1A is a front plan view showing an embodiment of an electrode package according to this invention;

FIG. 1B is a rear plan view showing the electrode package of FIG. 1A;

FIG. 1C is a cross-section view taken on line I-I′ in FIG. 1A;

FIGS. 2A to 2F are cross-section views showing an embodiment of a production method of the electrode package of FIG. 1A;

FIGS. 3A to 3C are cross-section views showing an embodiment of a production method of semiconductor devices using the electrode package of FIG. 1A;

FIG. 4 is an explanatory view for explaining a force F applied to a supports 23c and 23d of FIG. 1A;

FIG. 5 is a cross-section view showing an electrodeposited frame as an embodiment of conventional electrode packages; and

FIGS. 6A and 6B are cross-section views showing an embodiment of the conventional production method of semiconductor devices using the electrodeposited frame of FIG. 5.

### DESCRIPTION OF THE PREFERRED EMBODIMENT

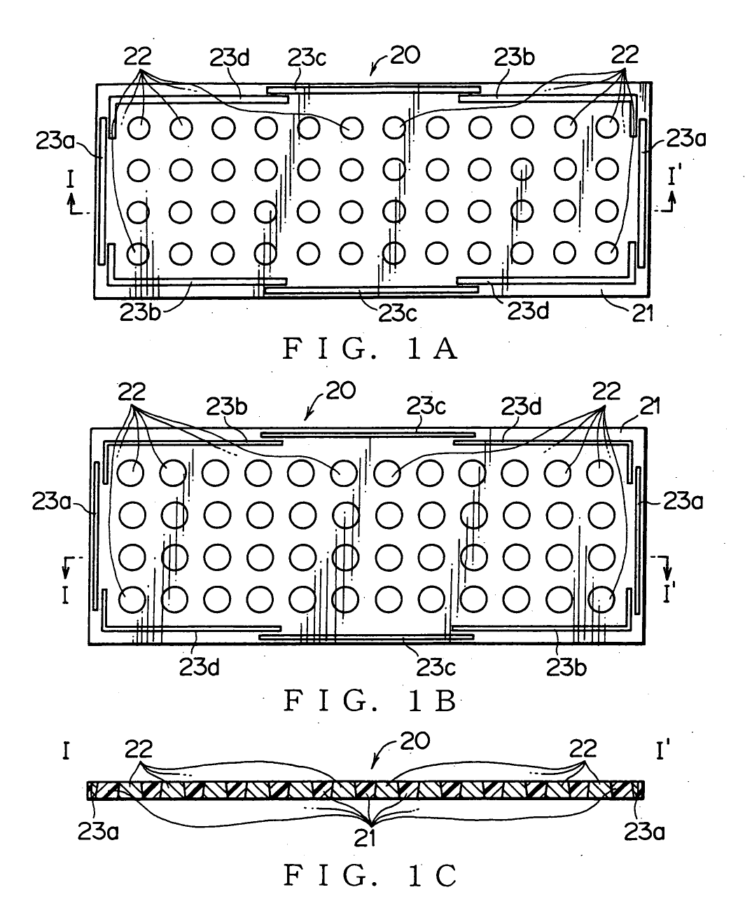

An electrode package and a semiconductor device using the electrode package according to this invention will be explained with reference to FIGS. 1A to 1C, 2A to 2F, 3A to 3C, and 4. Here, this invention relates to a leadless surface mounting type resin molded semiconductor device, and the electrode package used in production processes of the resin molded semiconductor device will be explained.

As shown in FIG. 1A, an electrode package 20 includes a resin plate 21. A plurality of isolated metal layers 22 (electrodes) having the same shapes are arranged in a matrix, and molded in the resin plate 21.

Further, the metal layers 22 are exposed from both upper and lower surfaces of the resin plate 21. Further, a cross-sectional area of each of the metal layers 22 is increased with depth from the upper surface to the lower surface of the resin plate 21.

Each metal layer 22 is configured with a thin Au (gold) or Sn (tin) layer (not shown) having high solderability at the upper surface as shown in FIG. 1A; a thin Au or Ag (silver) layer (not shown) being able to be connected to an Au wire at the lower surface as shown in FIG. 1B; and a thin Ni (nickel), Ni/Co (cobalt), or Cu (Copper) layer (not shown) formed by electrodepositing, and positioned between said two thin layers. Thicknesses of the Ni, Ni/Co, or Cu layer and the Au, Sn or Ag layer are 20 to 50 μm and 0.05 to 10 μm, respectively.

Further, in the electrode package 20, a reinforcing frame formed by a plurality of supports 23a, 23b, 23c, 23d in a longitudinal direction thereof being arranged along the periphery of the resin plate 21 is molded. For example, the supports 23a, 23b, 23c, 23d and the metal layers 22 are formed simultaneously by electrodeposition.

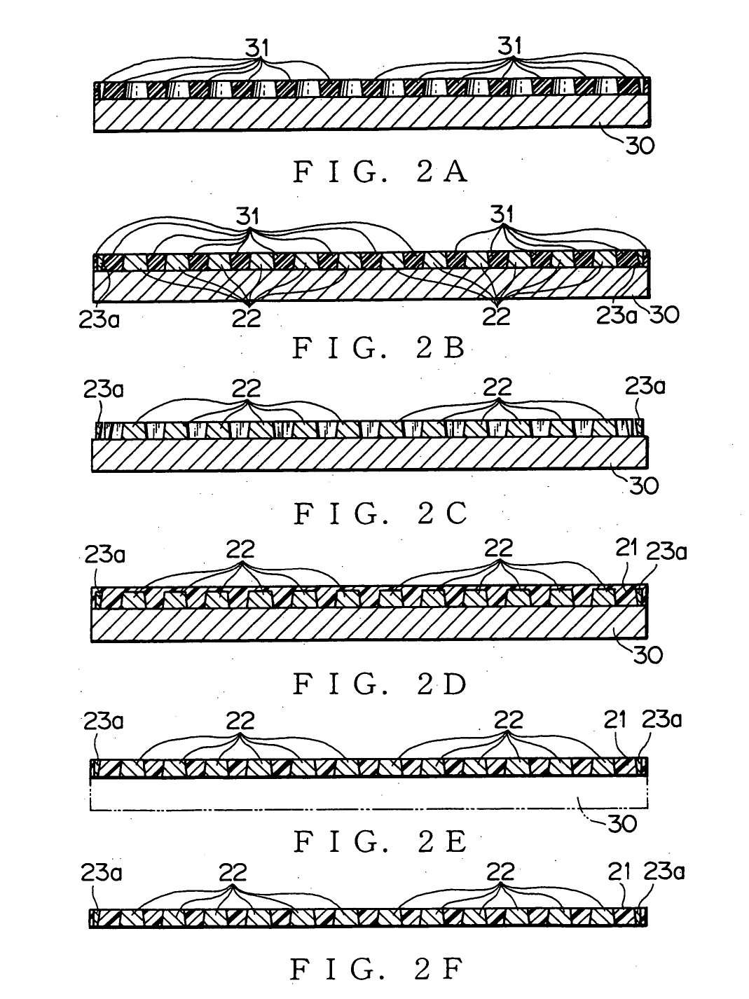

An embodiment of a production method of the electrode package 20 as shown in FIG. 1A will be explained with reference to cross-sections of FIGS. 2A to 2F. First, as shown in FIG. 2A, a flexible flat metal substrate 30 is prepared for producing the electrode package 20. The metal substrate 30 is a thin stainless steel plate, having 0.1 mm thickness. Then, a resist film 31 is formed on a surface of the metal substrate 30, except specific areas where the metal layers 22 or the supports 23a, 23b, 23c, 23d are to be formed. In addition, the resist film 31 is formed in a shape that a cross-sectional area is decreased with depth from its surface toward the metal substrate 30.

Then, the metal substrate 30 is dipped in an electrodeposition bath. Then, an electric current is applied between the metal substrate 30 and the electrode in the electrodeposition bath. In this way using an electrocasting process, as shown in FIG. 2B, by electrodepositing Au or Ag; Ni, Ni/Co or Cu; and Au or Sn sequentially, the metal layers 22 and the supports 23a, 23b, 23c, 23d configured with thin Au or Ag; Ni, Ni/Co or Cu; and Au or Sn films (not shown) are formed on areas, on which the resist film 31 is not formed, of the metal substrate 30. As described above, since the resist film 31 is formed in the shape that the cross-sectional area is decreased with depth from its surface toward the metal substrate 30, each metal layer 22 is inversely formed in a shape that a cross-sectional area is increased with depth from its surface toward the metal substrate 30.

Next, as shown in FIG. 2C, the resist film 31 is removed. Then, as shown in FIG. 2D, resin 21 is coated by, for example, a spin coating. Then, as shown in FIG. 2E, the whole surface of the resin 21 film is removed to expose the metal layers 22 at the upper surface of the resin 21 film. Then, as shown in FIG. 2F, the metal substrate 30 is removed to form the electrode package 20. Since the metal layers 22 and the supports 23a, 23b, 23c, 23d are electrodeposited in the metal substrate 30 using the electrocasting process, and the metal substrate 30 is flexible in a plane shape, the metal substrate 30 can be removed from the electrode package 20 easily.

In addition, the production process of this invention is not limited to the above-described process. For one example, a process, in which thin layers (not shown) of Au or Ag; Ni, Ni/Co or Cu; and Au or Sn are electrodeposited or vacuum deposited using, for example, a flash evaporation method, and then thin film is removed by etching, except the metal layers 22 and the supports 23a, 23b, 23c or 23d, can be adapted. For another example, a process, in which firstly only one thin layer of Ni, Ni/Co, or Cu is resin coated, secondly the metal substrate 30 is removed from the resin plate, and thirdly the resin plate is dipped in the electrodeposition bath so that the thin layers are electrodeposited on one layer at both the upper and lower surfaces of the resin plate simultaneously, can also be adopted.

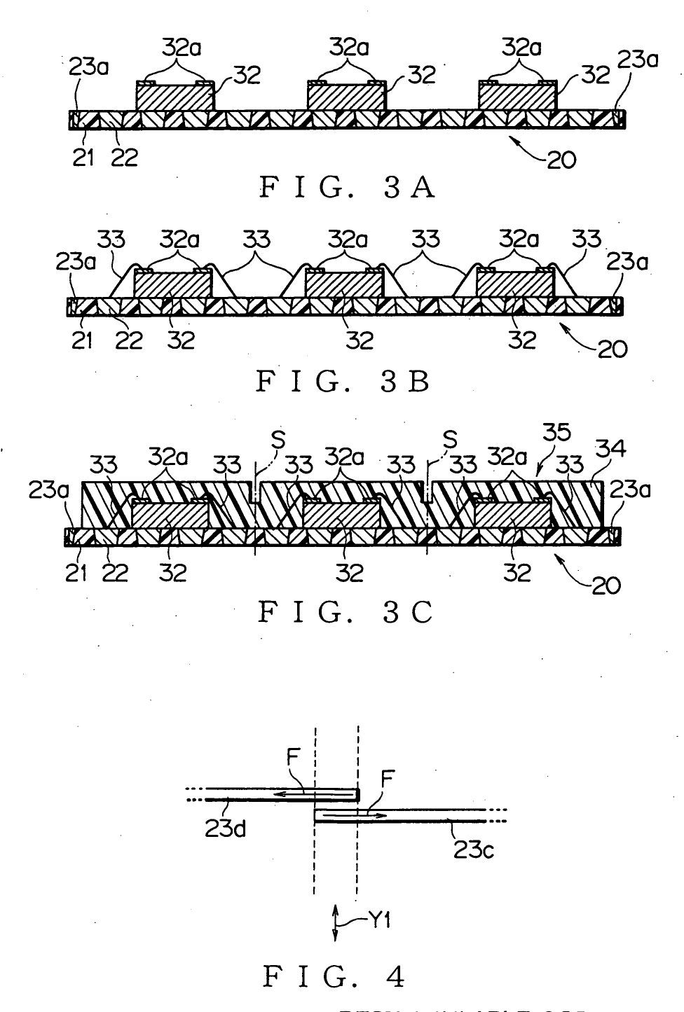

The electrode package 20 described above is delivered to a maker of semiconductor devices. At the maker, semiconductor chips are mounted on the electrode package 20 to produce semiconductor devices. In the following, a production method of the semiconductor device using the electrode package 20 will be explained with reference to FIGS. 3A to 3C. At first, as shown in FIG. 3A, semiconductor chips 32 are mounted and die-bonded on the upward lower surface of the electrode package 20. Bonding pads 32a are formed on a surface of each semiconductor chip 32.

After the semiconductor chips 32 are mounted, as shown in FIG. 3B, Au wires 33 electrically connect the bonding pads 32a of each semiconductor chip 32 with the metal layers 22. The Au wires 33 are connected by ultrasonic bonding or the like. Then, the electrode package 20, on which the semiconductor chips 32 are mounted, and wire-bonded, is attached to an upper mold 34.

Epoxy resin is injected into an encapsulated inner space between the upper mold 34 and a lower mold (electrode package 20), via a cavity formed on the upper mold 34. In this mold set, the electrode package 20 works as a lower mold set. In this process, the semiconductor chips 32 connected with the wire 33 are capsulated in the resin, and a resin encapsulated body 35 is formed having the semiconductor chips 32 and the metal layers 22 as shown in FIG. 3C. Then, semiconductor devices 32 are separated from the resin encapsulated body 35 by cutting it along cutting plane lines S.

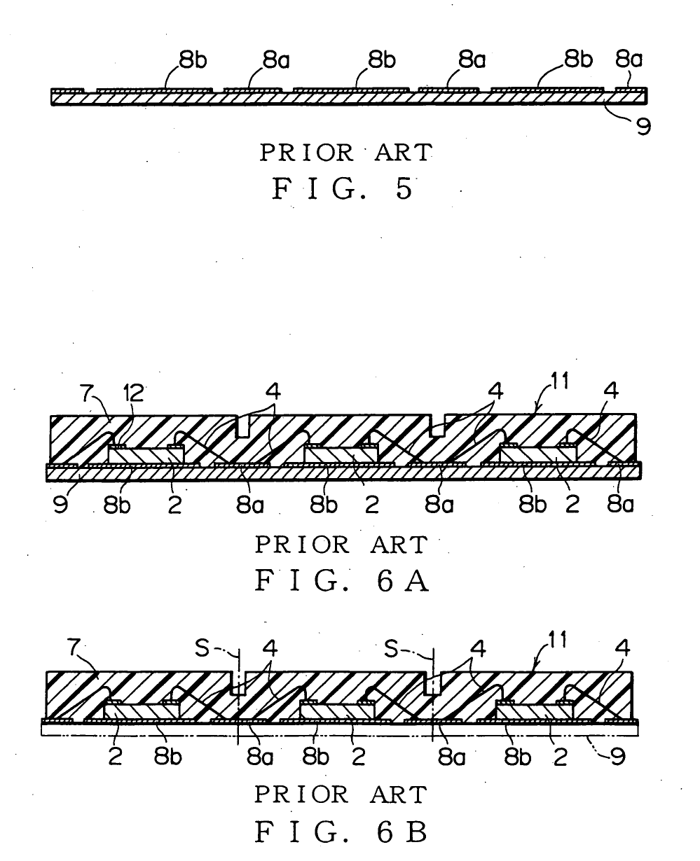

According to the electrode package 20 of this invention as shown in FIG. 1A, a plurality of metal layers 22 isolated from each other are supported by the resin plate 21. Therefore, the electrode package 20 can be made without a conventional metal substrate and can be lighter in weight. Therefore, a delivery cost of the electrode packages 20 to the makers of the semiconductor devices can be reduced. Further, according to this invention, as shown in FIGS. 3A to 3C, there is no need to remove the metal substrate (for example, reference number 9 in FIG. 5) in the production process of the semiconductor devices. Therefore, there is no need for each maker of the semiconductor devices to possess an apparatus for removing the metal substrate. Thus, production costs of the semiconductor devices can be reduced.

As shown in FIG. 1C, the cross-sectional area of each of said metal layers 22 is increased with depth from the upper surface to the lower surface of the resin plate 21. Therefore, a delivery in a way that the electrode package 20 is faced downward prevents the metal layers 22 from falling out of the resin plate 21. Therefore, quality of the electrode package 20 is stabilized to reduce the production cost of the semiconductor devices.

As shown in FIGS. 1A and 1B, the metal layers 22 have the same shapes, are arranged in a matrix, and are molded in the resin plate 21 of the electrode package 20. Therefore, the semiconductor chips 32 having various sizes and shapes can be mounted on the resin plate 21. Therefore, the number of electrode packages 20 applied to the semiconductor chips 32 having various sizes and shapes can be reduced. This also can reduce the production cost of the semiconductor devices 32.

As shown in FIG. 1B, a reinforcing frame is formed by a plurality of supports 23a, 23b, 23c, 23d along the periphery of the resin plate 21. The electrode package 20 is thin, about 25 μm thick, and its rigidity is low. Therefore, the reinforcing frame is provided to increase the rigidity of the electrode package 20. Thus, the number of defective electrode packages caused by deformations of the electrode package 20 decreases to reduce the production cost of the semiconductor devices.

In the electrode package 20, the reinforcing frame is formed by a plurality of supports 23a, 23b, 23c, 23d in a longitudinal direction thereof being arranged along the periphery of the resin plate 21. Further, as shown in FIG. 4, each pair of ends of neighboring supports 23a, 23b, 23c, 23d are overlapped in a direction Y1 perpendicular to the longitudinal direction. According to this arrangement, for example, even if the supports 23a, 23b, 23c, 23d are made of resin, a difference between coefficients of thermal expansion of the metal layers 22 and the resin plate 21, both of which are components of the electrode package 20, causes a difference between coefficients of thermal expansion of the electrode package 20 and the supports 23a, 23b, 23c, 23d. Thus, if forces F are applied to the electrode package 20 in a direction from each edge to each center of the supports 23a, 23b, 23c, 23d, the forces F are cancelled at each overlapping part. Therefore, it becomes harder to deform the electrode package 20.

As shown in FIGS. 3A to 3C, the semiconductor chips 32 are mounted on the lower surface of the electrode package 20 on which metal layers 22 have wider cross-section areas. According to this, even if bonds between the semiconductor chips 32 metal layers 22, on which the semiconductor chips 32 are mounted respectively, are broken, the semiconductor chips 32 are difficult to fall out from the resin plate 22. Therefore, the number of defective semiconductor devices is reduced and the production cost of the semiconductor devices is also reduced.

In the embodiment described above, each metal layer 22 is configured with a thin Au or Sn layer having high solderability; a thin Au or Ag layer being able to be connected to an Au wire; and a thin Ni, Ni/Co, or Cu layer positioned between said two thin layers. However, various configurations can be adopted. For example, in a process of mounting the semiconductor chips 32, when depositing thin films, the metal layers 22 can be configured with only a thin film of Ni, Ni/Co, or Cu, or with two of the films and any one of an Au or Sn film, or an Au or Ag film. Further, material for the metal layers 22 is not limited to those described above, and various materials, each of which can be an electrode, can be adopted.

What is claimed is:

1. An electrode package comprising:
a resin plate; and
a plurality of isolated electrodes molded in said resin plate,
whereby each of said electrodes is exposed from both upper and lower surfaces of the resin plate,
wherein said electrodes having a same shape are arranged in a matrix, and molded in the resin plate.
